(19) United States
(12) Patent Application Publication
(10) Pub. No.: US 2016/0111558 A1
(43) Pub. Date: Apr. 21, 2016

(54) PHOTOVOLTAIC CELLS HAVING A BACK SIDE PASSIVATION LAYER

(71) Applicant: CIMA NANOTECH ISRAEL, LTD., Industrial Park Caesarea (IL)

(72) Inventors: Wah Chung Wong, Belfield (AU); Hao Chen, Singapore (SG); Hua Gong, Singapore (SG); Annette Saenger, Singapore (SG); Dmitry Lekhtman, Afula (IL)

(21) Appl. No.: 14/785,567

(22) PCT Filed: May 8, 2014
(86) PCT No.: PCT/IB14/61310

§ 371 Date: Oct. 19, 2015

Related U.S. Application Data
(60) Provisional application No. 61/820,852, filed on May 8, 2013.

(51) Int. Cl. H01L 31/0216; H01L 31/18; H01L 31/0224

(52) U.S. Cl. CPC H01L 31/02167; H01L 31/022425; H01L 31/18

(57) ABSTRACT

A process for making a photovoltaic cell includes providing a semiconducting substrate having a back side passivation layer, and coating a self-assembling emulsion that includes glass frit particles onto the back side passivation layer. The emulsion is allowed to self-assemble into a network of traces that define cells. An electrode is formed over the network to create a precursor cell, which is then fired to cause the network to burn through the passivation layer and establish electrical contact between the semiconducting substrate and the electrode.

### CROSS-REFERENCE TO RELATED APPLICATIONS

This application claims the benefit of U.S. Provisional Application Ser. No. 61/820,852, filed May 8, 2013. The disclosure of the prior application is considered part of (and is incorporated by reference in) the disclosure of this application.

### TECHNICAL FIELD

This invention relates to manufacturing solar cells.

### BACKGROUND

Silicon photovoltaic (e.g., solar) cells having a back side passivation layer have been described in e.g. US 2009/0301557, US 2013/0056060, and US 2013/0061918, and include local back surface field (LBSF) cells, passivated emitter rear contact (PERC) cells, and passivated emitter rear locally-diffused (PERL) cells. Back side passivation can lead to increased light conversion efficiency by reducing carrier losses (e.g., surface recombination), but also requires the opening of conductive pathways through the dielectric passivation layer such that electrical contact can be established between the silicon substrate and the back electrode. Methods for opening such conductive pathways (i.e. “vias” or “perforations”) include the use of lasers as described in, e.g., US 2013/0056060, or chemical etching as described in, e.g., US 2013/0061918. Laser opening may introduce structural damage to the substrate crystal, while impurities may remain from chemical etching, potentially reducing the reliability of the solar cell.

### SUMMARY

In one aspect, a process for making a photovoltaic cell is described. The process includes providing a semiconducting substrate (e.g., a silicon substrate) having a back side passivation layer, and coating a self-assembling emulsion that includes glass frit particles onto the back side passivation layer. The back side passivation layer may be selected from the group consisting of aluminum oxide layers, silicon oxide layers, silicon nitride layers, and combinations thereof. The emulsion is allowed to self-assemble into a network of traces that define cells. An electrode is formed over the network to create a precursor cell. In some implementations, the electrode is opaque to visible light. The precursor cell is then fired to cause the network to burn through the passivation layer and establish electrical contact between the semiconducting substrate and the electrode.

The use of a coating that self-assembles into a network of traces and cells provides an improved process for opening conductive pathways (i.e. “burning through” or “firing through”) through a passivation layer, e.g., a back side passivation layer. The coating contains nanoparticles (e.g. glass frit) having the capability of penetrating the passivation layer during the firing process. The coating may also contain metallic nanoparticles to further enhance electrical contact between the back side electrode and the silicon substrate. Examples of suitable metal nanoparticles include silver nanoparticles, aluminum nanoparticles, silver-aluminum nanoparticles, and combinations thereof. Beneficially, there is no need to wash or remove the coating after the via opening process, since the residual components do not have a detrimental effect on reliability.

In some implementations, each trace has an average width that is less than 10 μm or less than 5 μm. The network may provide an areal coverage on the substrate of less than 10% or less than 5%.

In a second aspect, there is described a photovoltaic cell that includes: (a) a semiconducting substrate having a front side and a back side; (b) an electrode on the front side of the substrate; (c) a layer on the back side of the substrate comprising passivating regions separated by interconnected traces, where the individual traces have an average width of less than 10 μm and the interconnected traces provide an areal coverage on the back side of the substrate of less than 10%; and (d) a second electrode overlying the layer and in electrical contact with the semiconducting substrate. In some implementations, the interconnected traces provide an areal coverage on the back side of the substrate of less than 5%. In some implementations, the individual traces have an average width of less than 5 μm. In still other implementations, the individual traces have an average width of less than 5 μm and the interconnected traces provide an areal coverage on the back side of the substrate of less than 5%.

The terms “back side” or “back,” and “front side” or “front,” refer to orientation with respect to the light source, often the sun. “Front side” is the side that faces the light source, while “back side” is the side opposite the front side and facing away from the light source.

The term “nanoparticles” as used herein refers to fine particles small enough to be dispersed in a liquid to the extent they can be coated and form a uniform coating. This definition includes particles having an average particle size less than about three micrometers. For example, in some implementations, the average particle size is less than one micrometer, and in some embodiments the particles measure less than 0.1 micrometer in at least one dimension. The particles may be in the form of spheres, rods, wires, tubes, flakes, and the like.

The phrase “transparent to light” generally indicates light transparencies of between 30% and 95% in the wavelength range of about 370 nm to 770 nm.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional view of a back side passivated photovoltaic cell before the firing process.

FIG. 2 is a cross-sectional view of a back side passivated photovoltaic cell after the firing process.

Like reference symbols in the various drawings indicate like elements.

### DETAILED DESCRIPTION

A liquid emulsion containing glass frit particles, alone or in combination with metal nanoparticles, is used to form a transparent conductive layer that self-assembles to form a series of interconnected traces (e.g., lines) defining cells following application to the back side of a passivated semiconductor substrate. Useful semiconductor substrates include germanium, silicon-germanium epitaxial layers, or silicon, with silicon being used for the majority of solar cells. A variety of silicon substrates can be useful in back side passivated photovoltaic cells, including polycrystalline, multicrystalline, and monocrystalline silicon. These substrates are formed from thin silicon wafers doped with either donor impurities (i.e. n-type semiconductor layers) or acceptor impurities (i.e. p-type semiconductor layers) to provide layers having the desired electrical properties. Typically, a solar cell is fabricated from a p-type substrate, counter-doping the front side with n-type impurities such as phosphorus to form a shallow p-n junction. Alternatively, the front side can be doped using acceptor impurities such as boron to form the shallow p-n junction if an n-type substrate is used. Light is converted to electricity through absorption of photons and subsequent generation of mobile charge carriers, which will be pushed through the internal electrical potential at the p-n junction and collectable as current generated from the solar cell.

Silicon substrates may be coated with a dielectric layer or multiple layers having passivation and antireflective functions on the front side while the passivation function is more important on the back side. These dielectric layers may be formed from thermally grown, sputtered, vapor deposited, or atomic layer deposited materials, e.g. metallic compounds and silicon compounds such as aluminum oxide, silicon dioxide, or silicon nitride.

Both the front and back surfaces of the passivated silicon substrate are coated with metallic or highly electrically conductive materials used as electrodes to make contact between the silicon and the external electrical circuit. These electrodes may be formed by printing with metallic pastes (e.g. inks), sputter coating, electroplating, or by vapor deposition techniques. Front electrodes (e.g. the negative electrode if the substrate is p-type) must be largely transparent and may be in the form of thin grids with bus bars to minimize light shading. Back electrodes may fully cover the back side of the substrate or be arranged in interdigitated fingers for all back-contacted solar cell structures.

The emulsion applied to the substrate includes a continuous liquid phase and a dispersed liquid phase that is immiscible with the continuous liquid phase and forms dispersed domains within the continuous liquid phase. In some implementations, the continuous phase evaporates more quickly than the dispersed phase. One example of a suitable emulsion is a water-in-oil emulsion, where water is the dispersed liquid phase and the oil provides the continuous phase. The emulsion can also be in the form of an oil-in-water emulsion, where oil provides the dispersed liquid phase and water provides the continuous phase.

The continuous phase can include an organic solvent. Suitable organic solvents may include petroleum ether, hexanes, heptanes, toluene, benzene, dichloroethane, trichloroethylene, chloroform, dichloromethane, nitromethane, dibromomethane, cyclopentanone, cyclohexanone or any mixture thereof. Preferably, the solvent or solvents used in this continuous phase are characterized by higher volatility than that of the dispersed phase, e.g., the water phase.

Suitable materials for the dispersed liquid phase can include water and/or water miscible solvents such as methanol, ethanol, ethylene glycol, propylene glycol, glycerol, dimethyl formamide, dimethyl acetamide, acetonitrile, dimethyl sulfoxide, N-methyl pyrrolidone.

The emulsion may also contain at least one emulsifying agent, binder or any mixture thereof. Suitable emulsifying agents can include non-ionic and ionic compounds, such as the commercially available surfactants SPAN®-20 (Sigma-Aldrich Co., St. Louis, Mo.), SPAN®-40, SPAN®-60, SPAN®-80 (Sigma-Aldrich Co., St. Louis, Mo.), glyceryl monooleate, sodium dodecylsulfate, or any combination thereof. Examples of suitable binders include modified cellulose, such as ethyl cellulose with a molecular weight of about 100,000 to about 200,000, and modified urea, e.g., the commercially available BYK®-410, BYK®-411, and BYK®-420 resins produced by BYK-Chemie GmbH (Wesel, Germany).

Other additives may also be present in the oil phase and/or the water phase of the emulsion formulation. For example, additives can include, but are not limited to, reactive or non-reactive diluents, oxygen scavengers, hard coat components, inhibitors, stabilizers, colorants, pigments, IR absorbers, surfactants, wetting agents, leveling agents, flow control agents, thixotropic or other rheology modifiers, slip agents, dispersion aids, defoamers, humectants, and corrosion inhibitors.

The emulsions contain particles, e.g., glass frit particles, for burning through the passivation layer. A variety of glass frit particles are available and may include lead or be lead-free. Glass frit may include metal oxides such as lead, zinc, boron, bismuth, and tellurium. Particle sizes of glass frit may range from nano-sized to micron-sized, e.g., up to 5 μm or up to 10 μm. Preferably, the glass frit particle size is consistent with the self-assembly process such that the glass frit particles self-assemble into a network. In the case of larger glass frit particles, methods for reducing particle sizes may be employed, such as grinding or milling, prior to combining the particles with the emulsion. Glass frit particles may be present in the emulsion at concentrations ranging from 0.1 wt. % to 10 wt. %.

The emulsion may also include metal nanoparticles in combination with the glass frit particles. The metal nanoparticles may include conductive metals or mixture of metals including metal alloys selected from, but not limited to, the group of silver, gold, platinum, palladium, nickel, cobalt, copper, aluminum, silicide-forming metals, or any combination thereof. The metal nanoparticles may also contain dopants, e.g., elements or compounds from Groups II, III, V, and/or VI of the Periodic Table. Preferred metal nanoparticles include silver, silver-copper alloys, silver-aluminum, silver palladium, or other silver alloys or metals or metals alloys produced by a process known as Metallurgic Chemical Process (MCP) described in U.S. Pat. Nos. 5,476,535 and 7,544,229.

Specific examples of suitable emulsions are described in U.S. Pat. No. 7,566,360, which is incorporated by reference in its entirety. These emulsion formulations generally comprise between 40 and 80 percent of an organic solvent or mixture of organic solvents, from 0 to 3 percent of a binder, 0 to 4 percent of an emulsifying agent, 2 to 10 percent of metal powder and 15 to 55 percent of water or water miscible solvent.

The coating composition can be prepared by mixing all components of the emulsion. The mixture can be homogenized using an ultrasonic treatment, high shear mixing, high speed mixing, or other known methods used for preparation of suspensions and emulsions.

The composition can be coated onto the semiconductor substrate using bar spreading, immersing, spin coating, dipping, slot die coating, gravure coating, flexographic plate printing, spray coating, or any other suitable techniques. In some implementations, the homogenized coating composition is coated onto the semiconductor substrate until reaching a thickness of about 1 to 200 microns, e.g., 5 to 200 microns.

Prior to coating the emulsion on the substrate, the substrate can be pre-treated, e.g., with a coating, to improve certain properties. For example, the substrate may be provided with a primer layer to improve adhesion between the substrate and the coated emulsion.

After applying the emulsion to the semiconductor substrate; the liquid portion of the emulsion is evaporated, with or without the application of heat. When the liquid is removed from the emulsion, the nanoparticles self-assemble into a network-like pattern of traces defining cells that are transparent to light. The self-assembled network preferably provides low areal coverage (i.e. the area or percentage of the area of the substrate covered by the network) to maximize the area covered by the passivation layer, including areal coverages of less than 10% or even less than 5%. Areal coverage is determined by a combination of cell sizes (i.e. the openings in the network) and line widths (i.e. the width of the network lines). Self-assembled networks may provide average line widths that are narrower than typical printing processes, e.g. less than 10 μm or even less than 5 μm, thus providing lower areal coverages.

In some implementations, the cells are randomly shaped. In other implementations, the process is conducted to create cells having a regular pattern. An example of such a process is described in WO 2012/170684 entitled “Process for Producing Patterned Coatings,” filed Jun. 10, 2011, which is assigned to the same assignee as the present application and hereby incorporated by reference in its entirety. According to this process, the composition is coated on a surface of the semiconductor substrate and dried to remove the liquid carrier while applying an outside force during the coating and/or drying to cause selective growth of the dispersed domains, relative to the continuous phase, in selected regions of the substrate. Application of the outside force causes the non-volatile component (the nanoparticles) to self-assemble and form a coating in the form of a pattern that includes traces defining cells having a regular spacing (for instance, a regular center-to-center spacing), determined by the configuration of the outside force. Application of the outside force may be accomplished, for example, by depositing the composition on the substrate surface and then passing a Mayer rod over the composition. Alternatively, the composition can be applied using a gravure cylinder. In another implementation, the composition may be deposited on the substrate surface, after which a lithographic mask is placed over the composition. In the case of the mask, as the composition dries, the mask forces the composition to adopt a pattern corresponding to the pattern of the mask.

In each case, it is the outside force that governs the pattern (specifically, the center-to-center spacing between cells in the dried coating). However, the width of the traces defining the cells is not directly controlled by of the outside force. Rather, the properties of the emulsion and drying conditions are the primary determinant of the trace width. In this fashion, lines substantially narrower than the outside force can be readily manufactured, without requiring the difficulty and expense of developing processes, masters, and materials having very fine linewidth. Fine linewidth can be generated with the emulsion and drying process. However, the outside force can be used (easily and inexpensively) to control the size, spacing, and orientation of the cells of the network.

Following liquid removal and formation of the self-assembled layer, the layer may be sintered using thermal, laser, ultraviolet, laser, or other treatments and/or exposure to chemicals such as metal salts, bases, or ionic liquids.

Following liquid removal, formation of the self-assembled layer, and any optional sintering treatments, an electrode layer may be deposited, e.g., screen printed with conductive pastes or inks. Metallic conductive pastes include aluminum or silver pastes. Electrodes may be full-coverage (e.g., on the back side of the solar cell) or may be partial-coverage to allow light to pass through the electrode (e.g., transparent electrodes on the front side of the solar cell). In the case of full-coverage electrodes on the passivated back side, it is preferable that the metallic paste does not contain burn-through components such as glass frit. In the case of bifacial solar cells, partial-coverage electrodes may be provided on both surfaces of the cell to allow light penetration from either side.

After electrode deposition, the article is fired or co-fired (in e.g. a belt furnace) at moderately high temperatures to accomplish one or more of the following steps: baking off of organic materials (e.g. binders or solvents), firing-through, sintering, annealing, and alloying to provide good ohmic contact between the layers. Temperatures may be ramped or stepped up to the peak temperatures (e.g. 700-900 deg. C.). Peak temperatures are typically held for brief periods between a few seconds and a minute.

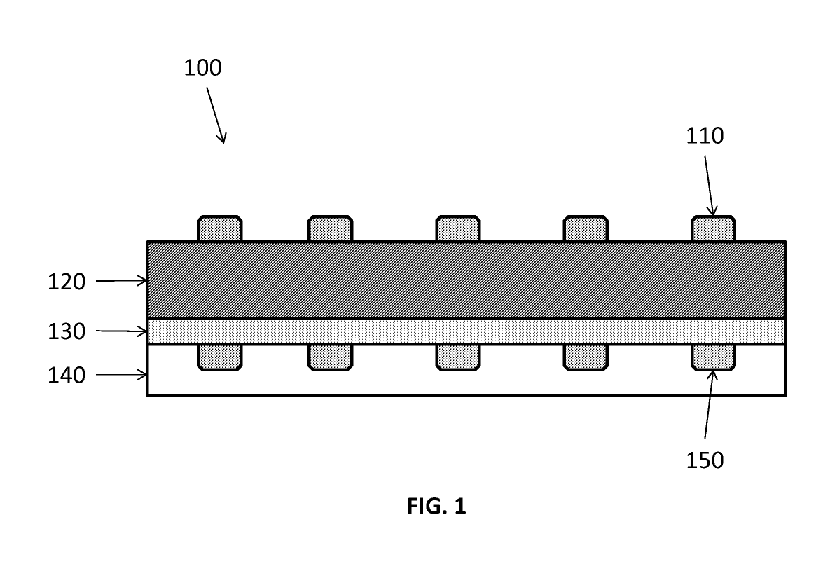

FIG. 1 shows a solar cell 100 before the firing process. 110 is the front electrode, 120 is the semiconductor wafer or substrate, 130 is the back side passivation layer, 140 is the back electrode, and 150 is the self-assembled network comprising glass frit and optionally conductive metal nanoparticles. The front surface of the solar cell may also have an antireflective coating, not shown. Prior to the firing process, the network 150 is on the surface of the back side passivation layer 130 and electrical contact between the back electrode 140 and semiconductor substrate 120 has not been established.

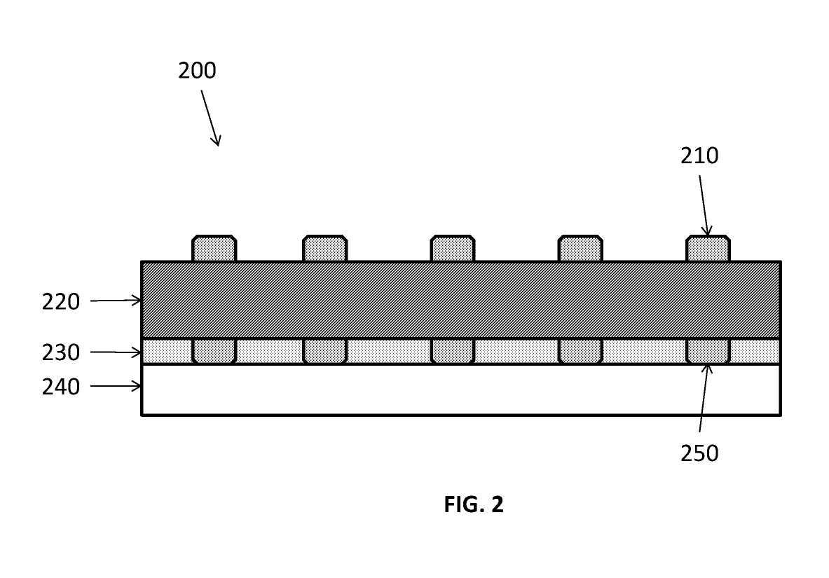

FIG. 2 shows a solar cell 200 after the firing process. 210 is the front electrode, 220 is the semiconductor wafer or substrate, 230 is the back side passivation layer, 240 is the back electrode, and 250 is the self-assembled network comprising glass frit and optionally conductive metal nanoparticles. After the firing process, the network 250 has penetrated through the back side passivation layer 230, thus establishing electrical contact between the back electrode 240 and the semiconductor substrate 220.

### EXAMPLES

### Glossary

| Component | Function | Chemical description | Source |
|---|---|---|---|
| BYK-410 | Liquid | Solution of a modified urea | BYK USA, |
| | rheology | | Wallingford, |
| | additive | | CT |
| BYK-106 | Wetting | Salt of a polymer with acidic groups | BYK USA |
| | and | | |
| | dispersing | | |
| | additive | | |
| Span 60 | Nonionic | Sorbitan monostearate | Sigma- |
| | surfactant | | Aldrich, St. |
| | | | Louis, MO |
| RS 610 | Anionic | Polyoxyethylene tridecyl ether phosphate, | Solvay- |
| | surfactant | available as Rhodafac 610 | Rhodia, |
| | | | Cranbury, |
| | | | NJ |
| BYK-348 | Silicone | Polyether modified polydimethylsiloxane | BYK USA |
| | surfactant | | |
| Disperbyk- | Wetting | Structured acrylate copolymer | BYK USA |
| 2025 | and | | |
| | dispersing | | |
| | additive | | |
| Cymel 1141 | Crosslinker | Highly alkylated mixed ether carboxylated | Cytec |
| | | melamine resin | Industries, |
| | | | Woodland |
| | | | Park, NJ |
| VIOX 0981 | Glass frit | Glass particles having SiO₂, PbO, and B2O₃, | Ceradyne |
| | for burn- | particle size about 0.5 um | VIOX, |
| | through | | Seattle, WA |
| Silver | | Silver nanoparticles | Cima |
| nanoparticle | | | Nanotech, |
| powder P204 | | | Inc., Israel |
| Silver- | | Silver-aluminum nanoparticles having 13.5% | Cima |
| aluminum | | by weight aluminum, available as Cat. No. | Nanotech, |
| nanoparticles | | 1414 | Inc. |
| Synperonic | Nonionic | Polyethylene glycol nonylphenyl ether | Fluka, |
| NP-30 | surfactant | | Sigma- |
| | | | Aldrich |
| | Emulsifier | Poly [dimethylsiloxane-co-[3-(2-(2- | Sigma- |
| | | hydroxyethoxy)ethoxy)propyl]methylsiloxane], | Aldrich |
| | | viscosity 75 cSt | |

TABLE 1
Example 1 emulsion composition

| Component | Weight (grams) |
|---|---|
| VIOX 0981 | 0.13 |
| RS 610 | 0.0026 |
| Toluene | 20.5 |
| P-xylene | 4.0 |
| Cyclohexanone | 2.3 |
| BYK-410 | 0.18 |
| Span 60 | 0.08 |
| Cymel 1141 | 0.06 |
| BYK-106 | 0.06 |
| P204 | 2.6 |

### Example 1

Multicrystalline silicon wafers (200 um thickness, 156×156 mm) were obtained from Tianwei Corporation, China. The front sides of the wafers had been surface textured, phosphorus-diffused to form the n-layer (having a sheet resistance of 70 Ohms/square), and coated with an 80 nm antireflection coating of silicon nitride. The back sides of the wafers had been coated (plasma enhanced chemical vapor deposition) with a 40 nm layer of silicon oxynitride followed by a 40 nm layer of silicon nitride.

The back side of the wafers were primed using an approximately 8 um wet thickness coating of a primer solution (0.6 wt. % Synperonic NP-30 and 0.3 wt. % Poly[dimethylsiloxane-co-[3-(2-(2-hydroxyethoxy)ethoxy)propyl]methylsiloxane] in 99.1 wt. % acetone). The primer was applied with a Mayer rod and allowed to air dry.

An emulsion was prepared by first mixing the components shown in Table 1 and sonicating until uniform to form Solution A. Next, 23.5 grams of a BYK-348 solution (0.04 wt % in DI water) was added to Solution A and sonicated until uniform to form Solution B. Finally, 0.17 g of BYK-106 and 0.32 g of Disperbyk-2025 solution (0.1 wt. % in toluene) were added to the solution B and mixed to form the final emulsion.

Next, the primed back side of the wafer was coated with the emulsion described above. The emulsion was coated using a Mayer rod to a wet coating thickness of 20-30 um, and the coating was allowed to dry, during which time the network self-assembled. The coated wafers were first placed in a 50 deg. C. oven for about a minute, then placed in a 150 deg. C. oven for 20 minutes.

Next, back side bus bars were screen printed using silver paste and a full coverage aluminum electrode was screen printed using aluminum paste. The front side electrode (H-grid) was printed using silver paste.

The wafer was next baked and co-fired using a 300-350 deg. C. baking step, a 450-600 deg. C. organic burn-off and alloying step, a 600-700 deg. C. pre-heating step, and an 800-900 deg. C. fire-through step, the final temperature being briefly maintained for less than 60 sec. Finally, a laser edge-isolation etch was done.

Four replicates were processed as described above and tested with standard solar cell test methods using a solar simulator, the results are reported in Table 2. The results demonstrate that the emulsion was capable of burning through the passivation layer, thus establishing ohmic contact.

TABLE 2
Example 1 test results

| | Open | Short | | | | |
|---|---|---|---|---|---|---|
| | Circuit | Circuit | Series | Shunt | Fill | |
| | Voltage | Current | Resistance | Resistance | Factor | |
| Rep- | (Voc, | (Isc, | (Rs, | (Rsh, | (FF, | Efficiency |
| licate | Volts) | amps) | Ohms) | Ohms) | %) | (%) |
| 1 | 0.589 | 7.957 | 0.002 | 4.742 | 76.680 | 15.045 |
| 2 | 0.591 | 8.026 | 0.002 | 2.463 | 75.763 | 15.035 |
| 3 | 0.582 | 8.008 | 0.001 | 0.938 | 71.215 | 13.884 |
| 4 | 0.591 | 7.986 | 0.002 | 1.085 | 74.135 | 14.640 |

### Example 2

Example 2 was prepared as described for Example 1, but without the addition of P204 silver nanoparticle powder to the emulsion.

TABLE 3
Example 2 emulsion composition

| Component | Weight (grams) |
|---|---|
| VIOX 0981 | 0.13 |
| RS 610 | 0.0026 |
| Toluene | 8.5 |
| P-xylene | 1.6 |
| Cyclohexanone | 0.9 |
| BYK-410 | 0.07 |
| Span 60 | 0.03 |
| Cymel 1141 | 0.02 |
| BYK-106 | 0.02 |

For the emulsion preparation, the components shown in Table 3 were mixed and sonicated until uniform to form Solution A. Then, 9.5 grams of a BYK-348 solution (0.04 wt % in DI water) was added to Solution A and sonicated until uniform to form Solution B. Finally, 0.06 g of BYK-106 and 0.1 g of Disperbyk-2025 solution (0.1 wt. % in toluene) was added to solution B and mixed to form the final emulsion for wafer back side coating

The sample was tested with standard solar cell test methods using a solar simulator, the results are shown in Table 4. The results demonstrate that the emulsion without silver nanoparticles was capable of burning through the passivation layer, thus establishing ohmic contact.

TABLE 4
Example 2 test results

| | Open | Short | | | | |
|---|---|---|---|---|---|---|
| | Circuit | Circuit | | Shunt | Fill | |
| | Voltage | Current | Series | Resistance | Factor | |
| Rep- | (Voc, | (Isc, | Resistance | (Rsh, | (FF, | Efficiency |
| licate | Volts) | amps) | (Rs, Ohms) | Ohms) | %) | (%) |
| 1 | 0.592 | 8.10 | 0.0038 | 31.29 | 75.23 | 15.11 |

### Example 3

Example 3 was prepared as described for Example 2, but with the addition of silver-aluminum nanoparticles to the emulsion.

### Silver-Aluminum Nanoparticle Preparation

840 grams of aluminum pellets (99.99% pure, nominal diameter 0.95 cm, C-KOE Metals L.P., Dallas, Tex.) were weighed into a ceramic crucible having a graphite interior. The crucible was placed into an induction furnace at 60% power (Opdel FS10 Induction Furnace, Opticom, Italy) under an Argon flow (about 1 L/min. Argon) until all of the aluminum had melted, about 6-7 min. 360 grams of silver pellets (silver granules, 99.99% purity, Umicore N.V., Belgium) were added to the melted aluminum inside the furnace and stirred several times using a graphite stirrer until the silver had melted, about 3-4 min., to form a homogeneous melt. The melt was immediately cast into a steel mold to form an ingot 250×115×15 mm.

First heat treatment: The ingot was placed into an electric furnace (Series K750, Heraeus GmbH, Germany) set at 400 deg. C. and held at that temperature for 2 hr. The furnace was turned off and the ingot was allowed to slowly cool before removal.

Using a rolling machine (BW-250, Carl Wezel KG, Germany), the ingot was passed through the rollers repeatedly, slowly decreasing the thickness of the ingot to form 1 mm strips. The rolled strips were cut into shorter lengths for further heat treatment.

Second heat treatment: The electric furnace was set at 220 deg. C. and the rolled strips were placed into the furnace and held at 220 deg. C. for 4 hr. The heat treated strips were removed from the furnace and quickly quenched in deionized water at 25 deg. C. or lower for 10-20 min.

On the same day as the second heat treatment, the strips were first surface-cleaned using 5% (wt/wt) sodium hydroxide in deionized water by immersing the strip until bubbles formed on the surface, about 2-3 min. For both the surface cleaning and the leaching, about 2 liters of NaOH solution was used for approximately 62 g. strips. The strips were immediately removed and rinsed with deionized water. Next, the strips were leached using 25% (wt/wt) sodium hydroxide in deionized water for 8-10 hrs. at approximately room temperature (due to the exothermic nature of the process, the liquid temperature increases throughout the process) to form a black powder. The leaching solution was decanted and replaced with deionized water repeatedly until the pH was approximately neutral. The black powder was then dried in a 40 deg. C. oven for about 24 hrs. The dried powder was then sieved through a 500 um sieve to form the final nanoparticle composition.

The aluminum content of the nanoparticle composition, as determined by ICP, was 13.50% by wt.

TABLE 5
Example 3 emulsion composition

| Component | Weight (grams) |
|---|---|
| VIOX 0981 | 0.13 |
| RS 610 | 0.0026 |
| Toluene | 20.5 |
| P-xylene | 4.0 |
| Cyclohexanone | 2.3 |
| BYK-410 | 0.18 |
| Span 60 | 0.08 |
| Cymel 1141 | 0.06 |
| BYK-106 | 0.06 |
| Silver-aluminum nanoparticles | 5.2 |

The sample was tested with standard solar cell test methods using a solar simulator, the results are shown in Table 6. The results demonstrate that the emulsion with silver-aluminum nanoparticles was capable of burning through the passivation layer, thus establishing ohmic contact.

TABLE 6
Example 3 test results

| | Open | Short | | | | |
|---|---|---|---|---|---|---|
| | Circuit | Circuit | Series | Shunt | | |
| | Voltage | Current | Resistance | Resistance | Fill | |
| Rep- | (Voc, | (Isc, | (Rs, | (Rsh, | Factor | Efficiency |
| licate | Volts) | amps) | Ohms) | Ohms) | (FF, %) | (%) |
| 1 | 0.6040 | 8.2284 | 0.0038 | 19.9301 | 77.0451 | 16.7406 |
| 2 | 0.6088 | 8.4143 | 0.0097 | 17.7279 | 68.6641 | 15.3782 |
| 3 | 0.6066 | 8.4003 | 0.0077 | 48.5036 | 71.1658 | 15.8534 |
| 4 | 0.6086 | 8.3374 | 0.0078 | 29.3215 | 71.3658 | 15.8315 |
| 5 | 0.6072 | 8.3822 | 0.0064 | 25.6555 | 72.9429 | 16.2292 |

A number of embodiments of the invention have been described. Nevertheless, it will be understood that various modifications may be made without departing from the spirit and scope of the invention.

What is claimed is:

1. A process for making a photovoltaic cell comprising:
(a) providing a semiconducting substrate having a back side passivation layer;
(b) coating a self-assembling emulsion comprising glass frit particles onto the back side passivation layer;
(c) allowing the emulsion to self-assemble into a network of traces that define cells;
(d) forming an electrode over the network to create a precursor cell; and
(e) firing the precursor cell to cause the network to burn through the passivation layer and establish electrical contact between the semiconducting substrate and the electrode.

2. A process according to claim 1 wherein the emulsion comprises glass frit particles and metal nanoparticles.

3. A process according to claim 2 wherein the metal nanoparticles are selected from the group consisting of silver nanoparticles, aluminum nanoparticles, silver-aluminum nanoparticles, and combinations thereof.

4. A process according to claim 1 wherein the semiconducting substrate comprises a silicon substrate.

5. A process according to claim 1 wherein the back side passivation is selected from the group consisting of aluminum oxide layers, silicon oxide layers, silicon nitride layers, and combinations thereof.

6. A process according to claim 1 wherein the traces have an average width that is less than 10 μm.

7. A process according to claim 1 wherein the traces have an average width that is less than 5 μm.

8. A process according to claim 1 wherein the electrode is opaque to visible light.

9. A process according to claim 1 wherein the network provides an areal coverage on the substrate of less than 10%.

10. A process according to claim 1 wherein the network provides an areal coverage on the substrate of less than 5%.

11. A photovoltaic cell comprising:
(a) a semiconducting substrate having a front side and a back side;
(b) an electrode on the front side of the substrate;
(c) a layer on the back side of the substrate comprising passivating regions separated by interconnected traces, where the traces have an average width of less than 10 μm and the interconnected traces provide an areal coverage on the back side of the substrate of less than 10%; and
(d) a second electrode overlying the layer and in electrical contact with the semiconducting substrate.

12. A photovoltaic cell according to claim 11 wherein the interconnected traces provide an areal coverage on the back side of the substrate of less than 5%.

13. A photovoltaic cell according to claim 11 wherein the traces have an average width of less than 5 μm.

14. A photovoltaic cell according to claim 11 wherein the traces have an average width of less than 5 μm and the interconnected traces provide an areal coverage on the back side of the substrate of less than 5%.
